(19) United States
(12) Patent Application Publication
(10) Pub. No.: US 2026/0158910 A1
(43) Pub. Date: Jun. 11, 2026

(54) IN-VEHICLE DEVICE

(71) Applicant: Panasonic Automotive Systems Co., Ltd., Kanagawa (JP)

(72) Inventors: Takashi ICHIHARA, Kanagawa Ken (JP); Yuki WATANABE, Kanagawa Ken (JP); Akira NOZAKI, Kanagawa Ken (JP); Ryuichi SUMIURA, Kanagawa Ken (JP); Arisa TAKABAYASHI, Tokyo To (JP)

(73) Assignee: Panasonic Automotive Systems Co., Ltd., Kanagawa (JP)

(21) Appl. No.: 19/413,810

(22) Filed: Dec. 9, 2025

(30) Foreign Application Priority Data
Dec. 10, 2024 (JP) 2024-216006

(51) Int. Cl. B60K 35/22; G06F 1/20; H05K 7/20

(52) U.S. Cl. CPC B60K 35/22; G06F 1/20; H05K 7/2039; H05K 7/20963; B60K 2360/691

(57) ABSTRACT

An in-vehicle device according to the present disclosure includes a housing, one or more boards, and side blocks. The housing is a container made of resin and provided with an opening on one of six surfaces of a box shape, and includes a pair of rails on a pair of surfaces facing each other among four surfaces excluding a back surface facing the opening, the rails extending in a direction from the opening toward the back surface. The side blocks are a pair of members to which both side portions of the one or more boards are fixed, are positioned such that longitudinal directions of the side blocks extend along the both side portions, and include sliders configured to slide along the rails while being guided by the rails.

### CROSS-REFERENCE TO RELATED APPLICATIONS

This application is based upon and claims the benefit of priority from Japanese Patent Application No. 2024-216006, filed on Dec. 10, 2024, the entire contents of which are incorporated herein by reference.

### FIELD

The present disclosure relates to an in-vehicle device.

### BACKGROUND

There is a demand for vehicles to have improved fuel efficiency and electricity consumption for considering the environment, and as a result, various in-vehicle devices used in the vehicles are also required to be lighter in weight.

Some in-vehicle devices of the related art are assembled by stacking a large number of parts (for example, JP 2020-205490 A). In a stacking method, the parts are stacked one by one in a height direction, and each time one part is stacked, the parts are fixed to each other by screws or the like. Therefore, the man-hours in an assembly work tends to be large, and thus, there is a demand for improved ease of assembly for such in-vehicle devices.

### SUMMARY

An in-vehicle device according to the present disclosure includes a housing, one or more boards, and side blocks. The housing is a container made of resin and provided with an opening on one of six surfaces of a box shape, and includes a pair of rails on a pair of surfaces facing each other among four surfaces excluding a back surface facing the opening, the rails extending in a direction from the opening toward the back surface. The side blocks are a pair of members to which both side portions of the one or more boards are fixed, are positioned such that longitudinal directions of the side blocks extend along the both side portions, and include sliders configured to slide along the rails while being guided by the rails.

### BRIEF DESCRIPTION OF THE DRAWINGS

FIG. 1 is a perspective view illustrating an example of an external appearance of an in-vehicle device according to an embodiment;

FIG. 2 is a diagram illustrating an assembly structure of a housing and an internal unit;

FIG. 3 is an exploded perspective view of the internal unit;

FIG. 4 is a perspective view illustrating an example of an external appearance of a side block;

FIG. 5 is a perspective view illustrating a rear corner of the housing as viewed from inside;

FIG. 6 is a perspective view illustrating a state in which the internal unit is half-pulled out from a predetermined position in the housing;

FIG. 7 is a plan view of a second board when the in-vehicle device is assembled;

FIG. 8 is a longitudinal sectional front view illustrating an example of a mounting state of the side block;

FIG. 9 is a diagram illustrating a ground path around the side block;

FIG. 10 is a diagram illustrating the ground path around the side block;

FIG. 11 is a diagram illustrating the ground path around the side block;

FIG. 12 is a plan view of the in-vehicle device;

FIG. 13 is an enlarged plan view of a bracket and its surrounding area of the in-vehicle device; and

FIG. 14 is a diagram for describing an example of arrangement around a cooling fan.

### DETAILED DESCRIPTION

Hereinafter, an embodiment of an in-vehicle device according to the present disclosure will be described with reference to the drawings. For easy description, a three-dimensional coordinate system is also illustrated in each drawing. In the three-dimensional coordinate system, a width direction of an in-vehicle device 1 (left-right direction) is defined as an X-axis direction, a depth direction (front-rear direction) is defined as a Y-axis direction, and a height direction (up-down direction) is defined as a Z-axis direction. The X-axis, the Y-axis, and the Z-axis are perpendicular to each other. A positive direction of the Z-axis is from bottom to top. A positive direction of the Y axis is a direction from a front side to a rear side of the in-vehicle device 1, and is also a forward moving direction of the vehicle. A positive direction of the X-axis is a direction from left to right of a user of the in-vehicle device 1.

### Structure

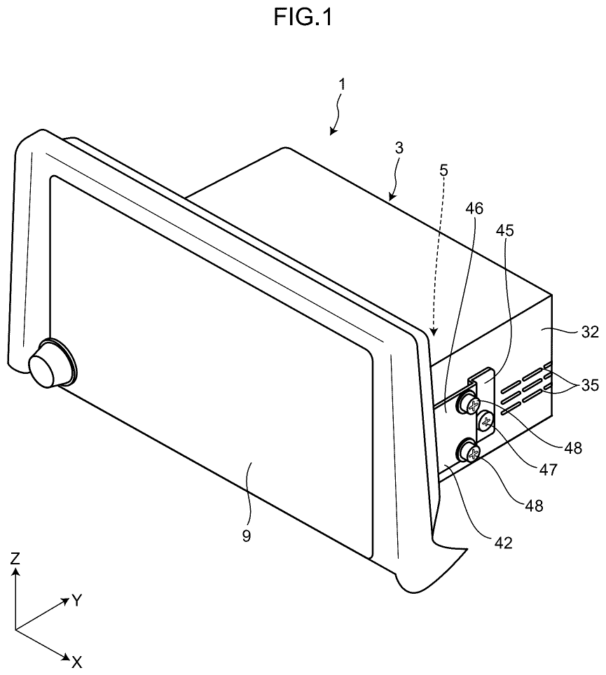

FIG. 1 is a perspective view illustrating an example of an external appearance of the in-vehicle device 1. The in-vehicle device 1 is, for example, a device that provides a navigation system, and includes a housing 3, an internal unit 5, a display 9, and the like.

The housing 3 is made of resin and accommodates the internal unit 5. Resin suitable as a material of the housing 3 is, for example, carbon fiber reinforced thermo plastics (CFRTP).

The display 9 is attached to a front surface of the housing 3 and the internal unit 5. For example, the housing 3 is inserted inside the vehicle from an opening provided on a front surface of a dashboard of a vehicle (into a depth side of the opening), and the display 9 is positioned in front of the dashboard.

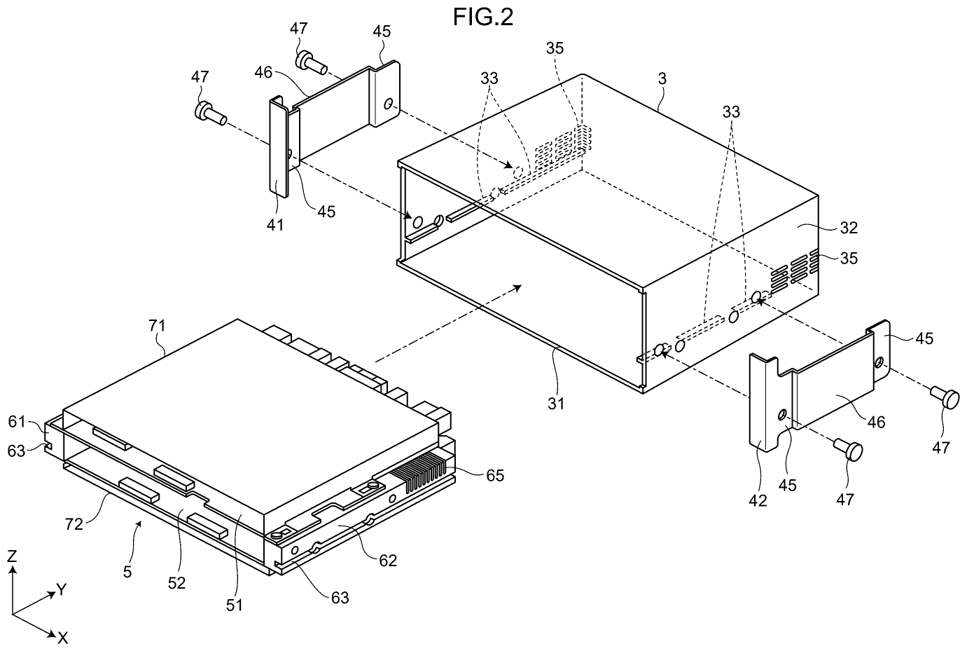

FIG. 2 is a diagram illustrating an assembly structure of the housing 3 and the internal unit 5. The housing 3 is a resin container provided with an opening 31 on one of six surfaces of a box shape. In other words, the housing 3 is a box-shaped container having a substantially rectangular parallelepiped shape provided with an open front surface and five surfaces.

The internal unit 5 is inserted from the opening 31 on the front surface of the housing 3, and is fixed together with brackets 41 and 42 attached to left and right side portions of the housing 3 by screws 47 from the outside of the housing. The screw 47 is an example of a second fastener having electrical conductivity.

The brackets 41 and 42 are metal plate members bent into a crank shape. Each of the brackets 41 and 42 is provided with two flat surfaces 45 and a flat surface 46 between the two flat surfaces 45. The flat surface 45 is attached to a side wall 32 of the housing 3 by the screws 47. The flat surface 46 is located away from the side wall 32 and is fixed to a vehicle body by a screw 48 illustrated in FIG. 1.

The brackets 41 and 42 and the screws 47 and 48 connect the in-vehicle device 1 to the vehicle body, and also function as a ground path (described below).

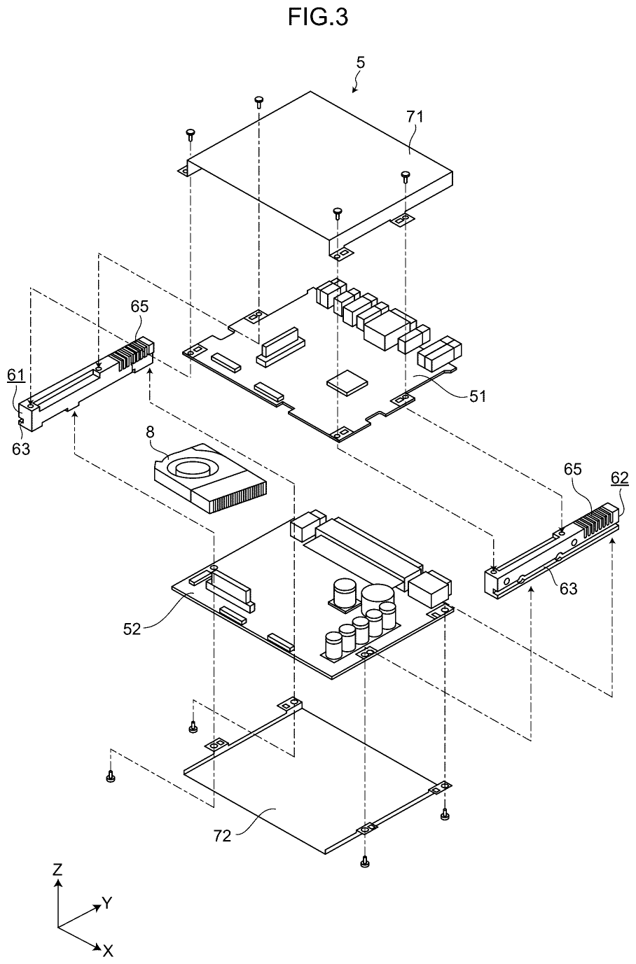

FIG. 3 is an exploded perspective view of the internal unit 5. The internal unit 5 provides a navigation system by cooperating with the display 9, and includes a first board 51, a second board 52, side blocks 61 and 62, an upper shield 71, a lower shield 72, a cooling fan 8, and the like. Both the upper shield 71 and the lower shield 72 (hereinafter sometimes collectively referred to as shields 71 and 72) are examples of electromagnetic shields.

Each of the first board 51 and the second board 52 (hereinafter sometimes collectively referred to as boards 51 and 52) is an example of one or more boards. The first board 51 is, for example, a CPU board, and the second board 52 is, for example, an audio board. The first board 51 is positioned so that a lower surface faces an upper surface of the second board 52.

The side blocks 61 and 62 each have a rectangular prism shape elongated in the depth direction, and are made of, for example, metal. The side blocks 61 and 62 are a pair of members to which both side portions of the boards 51 and 52 are fixed, and are positioned such that their longitudinal directions extend along the both side portions of the boards 51 and 52.

The side blocks 61 and 62 are disposed between the first board 51 and the second board 52 and on the left and right sides of the first board 51 and the second board 52. The first board 51 and the upper shield 71 are fixed to upper surfaces of the side blocks 61 and 62 by screws, and the second board 52 and the lower shield 72 are fixed to lower surfaces of the side blocks 61 and 62 by screws, thereby integrating various parts of the internal unit 5.

The upper shield 71 is made of, for example, a metal plate, and covers the first board 51 from above. The lower shield 72 is made of, for example, a metal plate, and covers the second board 52 from below. The upper shield 71 and the lower shield 72 have electrical conductivity and electromagnetically shield the first board 51 and the second board 52 from above and below, making it difficult for noise to enter into the internal unit 5.

The cooling fan 8 creates an air flow inside the internal unit 5, thereby preventing overheat of components that are heat sources on a board such as a system on a chip (SoC). The cooling fan 8 of the present embodiment is provided on the second board 52.

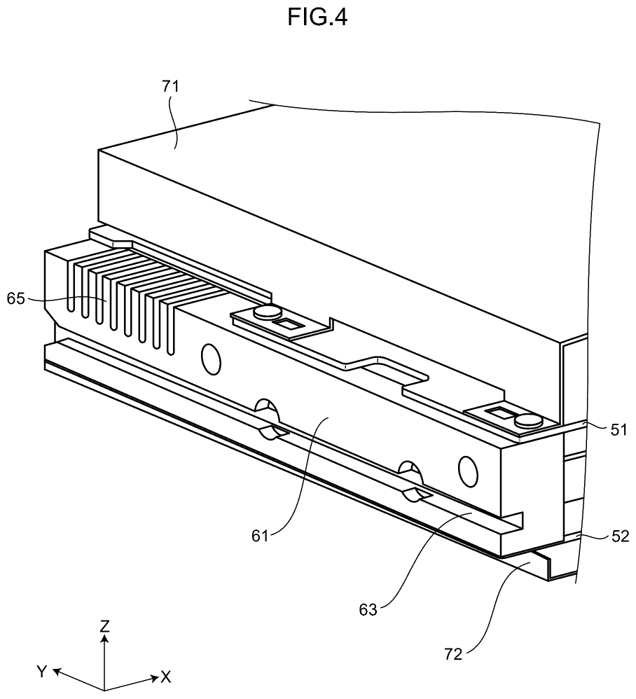

FIG. 4 is a perspective view illustrating an example of an external appearance of the side block 61. The side blocks 61 and 62 each include a heat sink portion 65 in a predetermined range near a rear end. To improve a function of the heat sink portion 65, it is preferable that metal as a material of the side blocks 61 and 62 is, for example, aluminum.

The heat sink portion 65 is a part of the side blocks 61 and 62, and is a portion in which a plurality of substantially parallel notches are provided so that a plurality of fins are arranged in a row. The notch of the heat sink portion 65 allows communication between inside and outside of the internal unit 5.

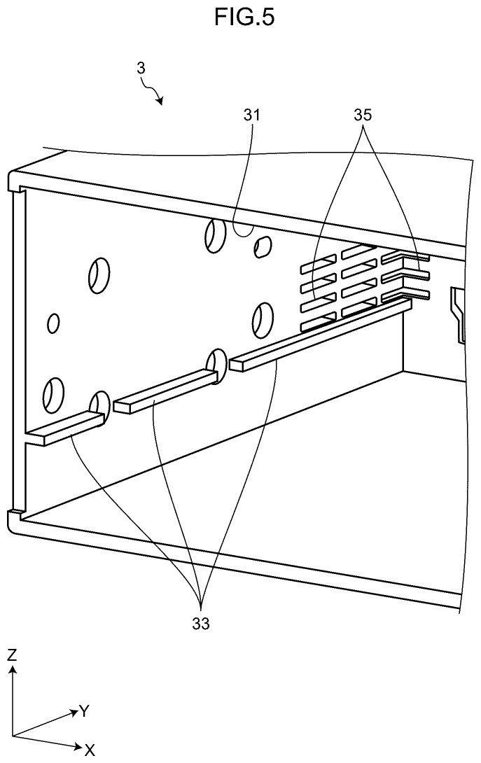

FIG. 5 is a perspective view illustrating a rear corner of the housing 3 as viewed from inside. The housing 3 is provided with rails 33 for guiding the internal unit 5 in the depth direction on inside of the left and right side walls 32.

The rail 33 protrudes inward from the housing 3 in a rib shape. A longitudinal direction of the rail 33 is aligned with a direction from the opening 31 toward a rear surface of the housing 3. The side walls 32 are an example of a pair of facing surfaces among four surfaces excluding a surface on a depth side facing the opening 31.

The housing 3 is provided with a ventilation hole 35 formed in a mesh shape at a corner on the depth side farther from the opening 31. The ventilation hole 35 functions as an intake port that takes air into the housing 3 and an exhaust port that expels air to outside the housing 3.

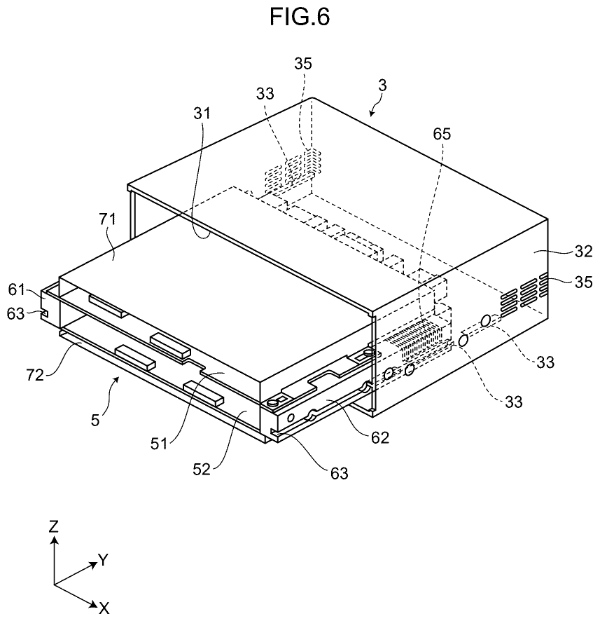

FIG. 6 is a perspective view illustrating a state in which the internal unit 5 is half-pulled out (or half-inserted) from a predetermined position in the housing 3. The internal unit 5 is provided with grooves 63 corresponding to the rails 33. The grooves 63 are provided on the side blocks 61 and 62. The groove 63 is an example of a slider that is guided by the rail 33 and moves by sliding along the rail 33.

During assembly, a worker aligns a position of the groove 63 of the internal unit 5 with the rail 33 of the housing 3, and inserts the internal unit 5 from the opening 31 of the housing 3. Accordingly, the internal unit 5 is guided by the rails 33. The internal unit 5 is guided along the rails 33 to a predetermined position in the housing 3.

When the internal unit 5 is accommodated in a predetermined position in the housing 3, the heat sink portion 65 is located near the ventilation hole 35. By inserting the rails 33 into the grooves 63, a position of the internal unit 5 relative to the housing 3 in the height direction is correctly determined.

### Cooling

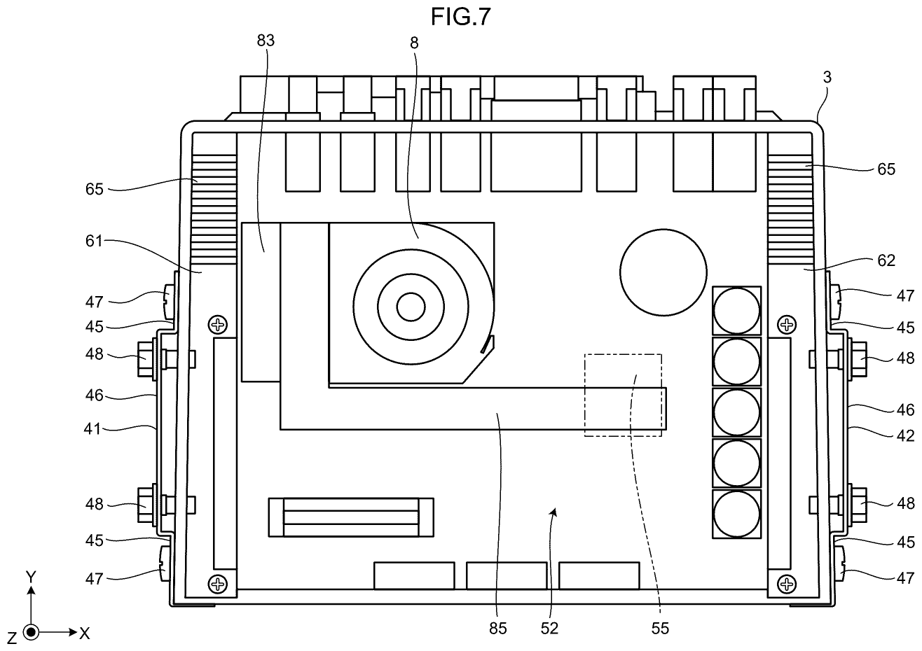

FIG. 7 is a plan view of the second board 52 when the in-vehicle device 1 is assembled. The internal unit 5 further includes a heat sink 83 and a heat pipe 85. The reference numeral 55 indicates a position where a component as a heat source is located (hereinafter, referred to as a heat source 55). The heat source 55 is, for example, an SoC mounted on the first board 51 and located above the second board 52.

The cooling fan 8 attached to the second board 52 is provided with an outlet directed toward the heat sink portion 65 of the side block 61. The heat sink 83 is provided between the outlet of the cooling fan 8 and the heat sink portion 65 of the side block 61 and is in contact with the side block 61.

The heat pipe 85 is disposed so that one end is in contact with the heat source 55 and the other end is in contact with the heat sink 83. The heat pipe 85 transfers heat from one end to the other end. As a result, heat generated by the heat source 55 is transmitted to the heat sink 83 and then to the side block 61. The heat sink 83 and the side block 61 (particularly, the heat sink portion 65) are cooled by an air flow formed by the cooling fan 8. Accordingly, overheat of the heat source 55 is prevented.

### Ground Path

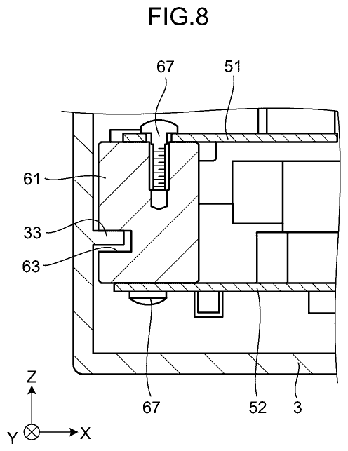

FIG. 8 is a longitudinal sectional front view illustrating an example of a mounting state of the side block 61. The side blocks 61 and 62 are supported in the housing 3 by the grooves 63 receiving the rails 33. The side blocks 61 and 62 fix the first board 51 above and the second board 52 under by screws 67 made of metal. The screws 67 penetrate through the boards 51 and 52 and are screwed into the side blocks 61 and 62 with screw heads in contact with surfaces of the boards 51 and 52. The screw 67 is an example of a first fastener having electrical conductivity.

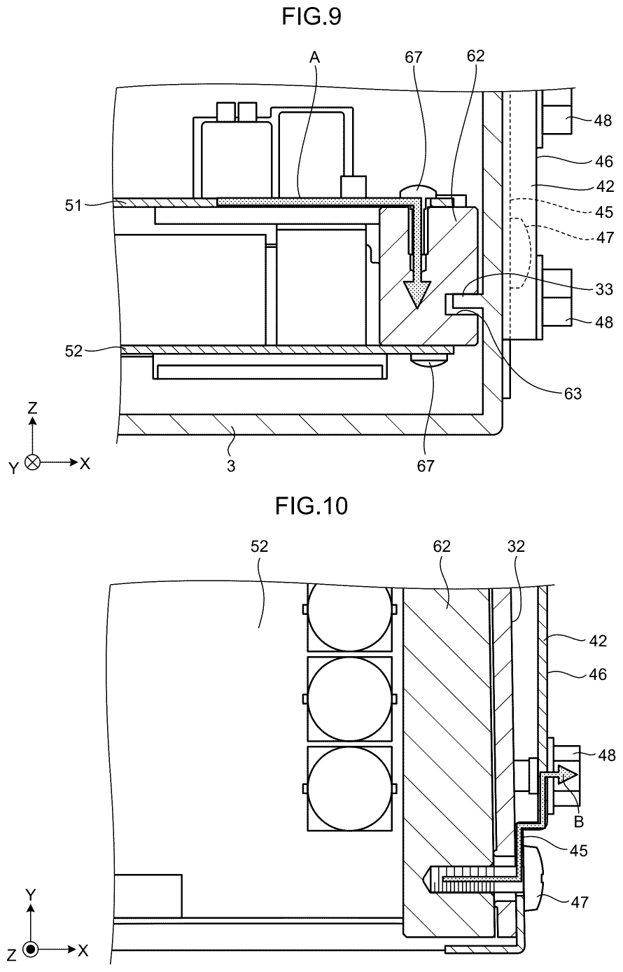

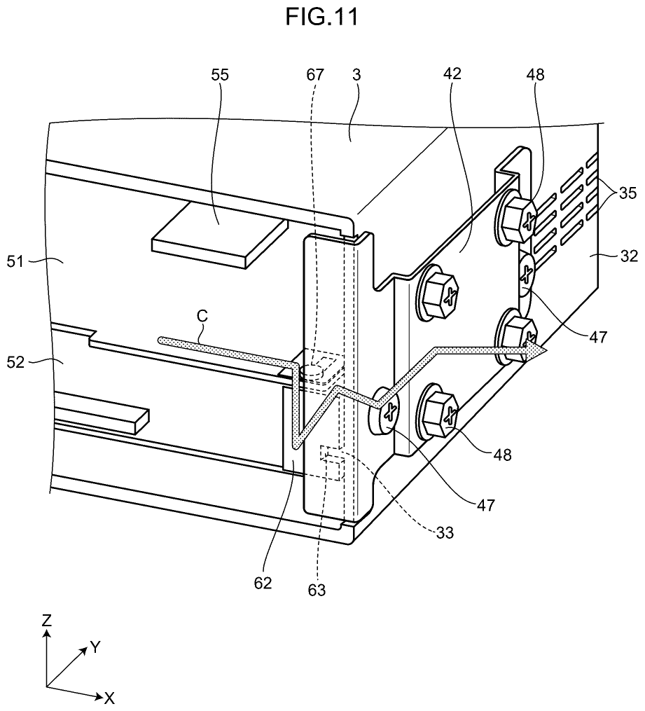

FIGS. 9 to 11 are diagrams illustrating a ground path around the side block 62. FIG. 9 is a longitudinal sectional front view, FIG. 10 is a transversal sectional plan view, and FIG. 11 is a perspective view. An arrow A illustrated in FIG. 9 indicates a ground path from the first board 51 to the side block 62. An arrow B illustrated in FIG. 10 indicates a ground path from the side block 62 to the vehicle body. An arrow C illustrated in FIG. 11 connects the ground path indicated by the arrow A and the ground path indicated by the arrow B.

As indicated by the arrows A to C, the ground path is connected from the first board 51 to the side block 62 via the screw 67, and further connected from the side block 62 to the bracket 42 or the vehicle body via the screws 47 and 48. By such a structure, it is possible to establish a ground path to the vehicle body without providing components dedicated for the ground path. Although the ground path is described above taking the first board 51 as an example, the same applies to the second board 52, and therefore a description thereof will be omitted.

### Draft

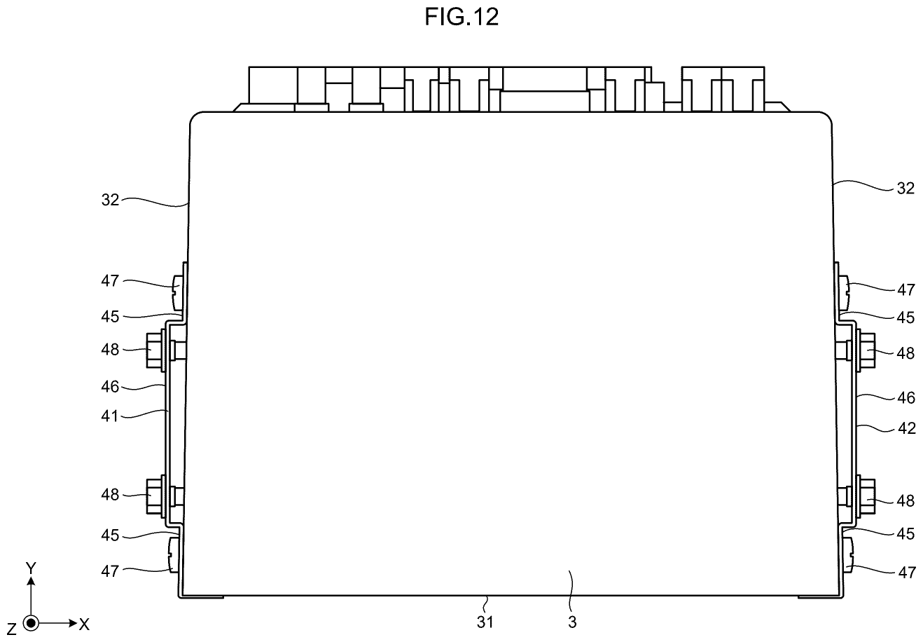

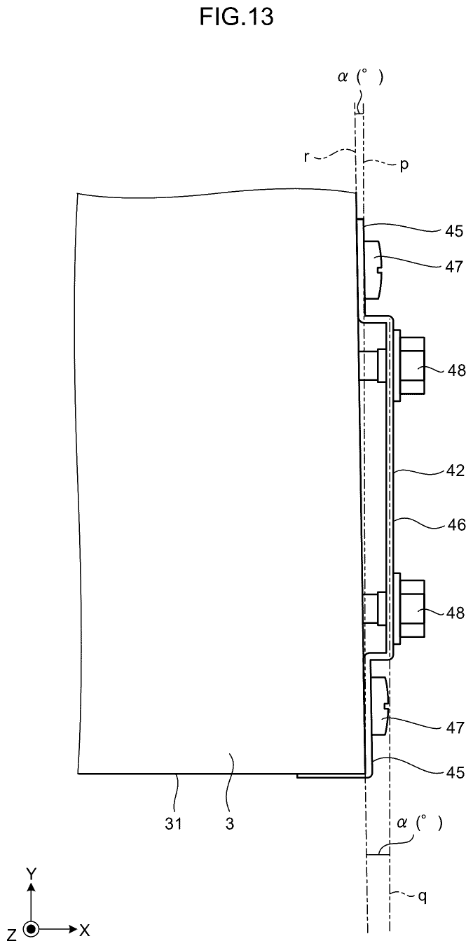

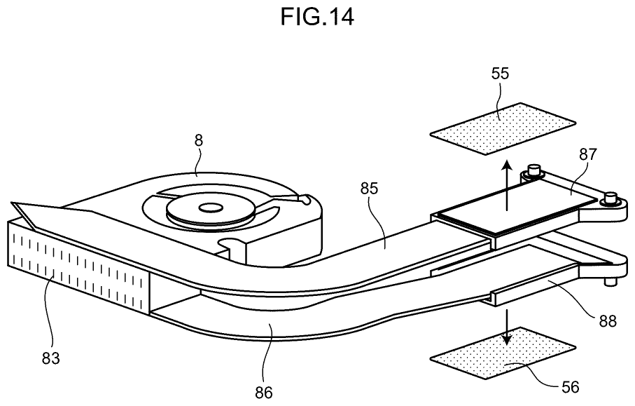

FIG. 12 is a plan view of the in-vehicle device 1. FIG. 13 is an enlarged plan view of the bracket 42 and its surroundings of the in-vehicle device 1.

The housing 3 is manufactured by injection molding in which resin is injected between a mold (cavity) that determines an outer shape of the housing 3 and a mold (core) that determines an inner shape with an edge of the opening 31 as a parting line. The housing 3 has a tapered shape with a draft in the depth direction from the viewpoint of mold releasability. In other words, a surface forming the housing 3 is inclined by α(°) from a depth side to a front side so that the opening 31 becomes wider. A draft angle α(°) is, for example, about 1 (°).

For easy description, FIG. 13 illustrates a two-dot chain line p, a one-dot chain line q, and a one-dot chain line r. The two-dot chain line p and the one-dot chain line q are parallel to the Y-axis direction. The one-dot chain line q is a line that follows an outer surface of the bracket 42 (a surface attached to the vehicle body).

The one-dot chain line r is a line that follows the side wall 32 of the housing 3 (see FIG. 12). An angle between the one-dot chain line q and the two-dot chain line p is the draft angle α(°).

Corresponding to the above-mentioned draft angle, the brackets 41 and 42 have a shape that offsets the angle α. In other words, the two flat surfaces 45 fixed to the side wall 32 are inclined by the angle α(°) equivalent to the draft angle with respect to the flat surface 46 fixed to the vehicle body.

Due to the shape of the brackets 41 and 42, even when the side wall 32 of the housing 3 has a draft inclination that did not exist in the structure of the related art, the in-vehicle device 1 can be attached to the vehicle body without requiring design changes on the vehicle body side.

An example of a procedure for assembling the in-vehicle device 1 having such a configuration will be described below.

First, a lower surface of the second board 52 is placed on an inner surface of the lower shield 72, next, lower surfaces of the side blocks 61 and 62 are aligned with both left and right sides of an upper surface of the second board 52, and then, the lower shield 72, the second board 52, and the side blocks 61 and 62 are fixed together by the screws 67.

Next, an upper surface of the first board 51 is placed on an inner surface of the upper shield 71, next, upper surfaces of the side blocks 61 and 62 are aligned with both left and right sides of a lower surface of the first board 51, and then, the upper shield 71, the first board 51, and the side blocks 61 and 62 are fixed together by the screws 67. Accordingly, the internal unit 5 is assembled.

Next, the assembled internal unit 5 is inserted into the opening 31 of the housing 3. Here, height positions of the grooves 63 and the rails 33 are adjusted so that the rails 33 fit into the grooves 63, and the internal unit 5 is slid toward the depth side of the housing 3 while the rails 33 are fitted into the grooves 63.

Next, the flat surfaces 45 of the brackets 41 and 42 are attached to both sides of the housing 3 by the screws 47. By the above steps, the in-vehicle device 1 is completed. The completed in-vehicle device 1 is mounted on the vehicle body by attaching the flat surfaces 46 of the brackets 41 and 42 to predetermined positions on the vehicle body by the screws 48.

As described above, the structure according to the present embodiment can provide the following advantages.

First, in the in-vehicle device 1, the housing 3 that covers the boards 51 and 52 is made of resin so that a weight can be reduced compared to the in-vehicle devices of the related art.

In the in-vehicle devices assembled by the stacking method of the related art, a portion corresponding to the housing 3 is formed by a plurality of metal plates, whereas in the housing 3 of the present embodiment, five surfaces are integrally formed. According to the structure of the present embodiment, even when the housing 3 is made of resin instead of metal, it is possible to obtain a sufficient strength comparable to that of the housings of the related art.

According to the present embodiment, the number of screws and the like required for assembly is reduced compared to the in-vehicle devices assembled by the stacking method of the related art, so that the in-vehicle device 1 can be made lighter in weight.

According to the structure of the present embodiment, the number of assembly steps can be reduced by reducing the number of screw fastening points during assembly, thereby improving ease of assembly.

By the structure of the present embodiment, the number of points fixed by screws or the like is reduced, and therefore the number of points at which abnormal noise is generated due to vibration is reduced. Therefore, according to the structure of the present embodiment, the number of points requiring measures against abnormal noise can be reduced, weight can be reduced, and ease of assembly can be improved.

According to the structure of the present embodiment, the internal unit 5 is assembled by inserting and sliding the internal unit 5 into the housing 3, eliminating the need for positioning during assembly or supporting of components during assembly, reducing the man-hours and improving ease of assembly.

In the stacking method of the related art, shapes of the boards 51 and 52 tend to be irregular, but the structure of the present embodiment makes it easier to design the boards 51 and 52 in a simple shape that is approximately a rectangular shape. Accordingly, the shape of a punching die for the boards 51 and 52 is also simplified. Since cutting is efficient, the cost of parts can be reduced.

By providing the heat sink portion 65 on the side blocks 61 and 62, heat dissipation performance of the in-vehicle device 1 can be improved.

According to the present embodiment, by connecting the heat sink 83 cooled by the cooling fan 8 to the heat source 55 via the heat pipe 85, cooling of the heat source 55 can be promoted.

The housing 3 of the present embodiment has a tapered shape due to draft. Accordingly, effects of errors due to accumulation of dimensional tolerances are reduced during mounting of components on the vehicle body. In other words, for example, when the housing 3 is inserted inside the vehicle from the opening provided on the front surface of the dashboard of the vehicle (into a depth side of the opening), the housing 3 can be easily inserted into the opening, and the in-vehicle device 1 can be easily accommodated in a predetermined position on the vehicle body side. Accordingly, it is possible to reduce the man-hours. It is possible to improve the yield of the housings 3 by the above-described relaxation.

As described above, according to the present embodiment, the weight of the in-vehicle device 1 can be reduced and ease of assembly can be improved.

In the present embodiment, the in-vehicle device 1 that provides a navigation system is described as an example, but the present invention is not limited thereto, and the in-vehicle device 1 may be other type of device. The in-vehicle device 1 may be a device that performs various electronic controls such as audio system control, engine control, and advanced driver-assistance systems (ADAS) control.

The above-described embodiment can be modified as appropriate by changing a part of a configuration or a function of each of the above-described devices. Therefore, some modification examples of the above-described embodiment will be described below. In the following, differences from the above-described embodiment will be mainly described, the same reference numerals will be used for the same parts as those already described, and detailed description will be omitted. The modification examples described below may be implemented individually or in appropriate combination.

### First Modification Example

In the above embodiment, the heat sink 83 is provided between the cooling fan 8 and the heat sink portion 65 of the side blocks 61 and 62, but the present invention is not limited thereto.

For example, the heat sink portion 65 and the outlet of the cooling fan 8 may be disposed near each other, and the heat sink 83 may not be provided. Then, the heat sink 83 becomes unnecessary and the weight of the in-vehicle device 1 can be further reduced. Here, it is preferable that the heat pipe 85 is disposed to connect the heat source 55 to the heat sink portion 65.

### Second Modification Example

FIG. 14 is a diagram for describing an example of arrangement around the cooling fan 8. In the drawing, another heat source 56 is illustrated indicated by a reference numeral 56. The heat source 56 is, for example, a component provided on the second board 52. In the present example, the internal unit 5 further includes a second heat pipe 86. Reference numerals 87 and 88 denote members for closely attaching the heat pipes 85 and 86 to the heat sources 55 and 56.

According to such a configuration, one cooling fan 8 can promote heat transfer from the heat sources 55 and 56 located above and below the cooling fan 8, thereby preventing overheat of the heat sources 55 and 56.

In FIG. 14, the heat source 55 and the heat source 56 are spaced apart in the height direction and are positioned to overlap in a plan view, but such a configuration is not necessary in practice. In other words, the heat source 55 and the heat source 56 may be positioned apart from each other in a plan view as long as one ends of the heat pipes 85 and 86 are in contact with the heat sources.

### Third Modification Example

In the above embodiment, the shields 71 and 72 are sub-assembled (Sub ASSY) to the internal unit 5, and the boards 51 and 52 are protected from noise by covering the boards with the upper shield 71 and the lower shield 72, but the present invention is not limited thereto, and electromagnetic shielding may be performed by other methods.

For example, there is a method in which, when the housing 3 is injection-molded, a foil such as aluminum is insert-molded. By such a method, the upper shield 71 and the lower shield 72 become unnecessary. An outline of insert molding will be described below.

The insert molding is performed, for example, according to the following steps (1) to (3).
(1) When closing the mold, aluminum foil is interposed between the cavity and the core.
(2) The mold is filled with resin.
(3) The mold is opened and the molded product is removed from the core.

According to the above method, resin forming the housing 3 is integrated with the aluminum foil. Therefore, even when the shields 71 and 72 are not provided, by accommodating the boards 51 and 52 in the housing 3, the boards 51 and 52 can be surrounded by aluminum foil. Accordingly, it is possible to protect the boards 51 and 52 from noise.

The aluminum foil is suitable for insert molding since the aluminum foil does not impair functionality even when the foil is wrinkled and does not ruin appearance as long as the foil is inside the housing 3.

According to the structure of the in-vehicle device according to the present disclosure, a device can be made lighter and ease of assembly can be improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An in-vehicle device comprising:
a housing that is a container made of resin and provided with an opening on one of six surfaces of a box shape, and includes a pair of rails on a pair of surfaces facing each other among four surfaces excluding a back surface facing the opening, the rails extending in a direction from the opening toward the back surface;
one or more boards; and
side blocks that are a pair of members to which both side portions of the one or more boards are fixed, are positioned such that longitudinal directions of the side blocks extend along the both side portions, and include sliders configured to slide along the rails while being guided by the rails.

2. The in-vehicle device according to claim 1, wherein
the one or more boards and the side block are fixed by a first fastener having electrical conductivity, and
the side block is electrically conductive and fixed to the housing by a second fastener having electrical conductivity together with a bracket made of metal, located such that a surface of the housing on which the rail is provided is interposed between the bracket and the side block, and fixed to a predetermined position on a vehicle body.

3. The in-vehicle device according to claim 2, further comprising an electromagnetic shield surrounding the one or more boards, wherein the electromagnetic shield is fixed to the side block together with the one or more boards by the first fastener.

4. The in-vehicle device according to claim 1, wherein the side block is made of metal and is provided with a heat sink portion in which a plurality of fins are arranged at least partially.

5. The in-vehicle device according to claim 4, wherein a heat pipe is provided between a component as a heat source of the one or more boards and the heat sink portion.
